(19) United States
(12) Patent Application Publication
(10) Pub. No.: US 2025/0210368 A1
(43) Pub. Date: Jun. 26, 2025

(54) SINGLE MASK MULTI-CRITICAL DIMENSION ETCHING USING ETCH STOP

(71) Applicant: Tokyo Electron Limited, Tokyo (JP)

(72) Inventors: Matthew Ocana, Albany, NY (US); Joshua Baillargeon, Albany, NY (US); Minjoon Park, Albany, NY (US)

(21) Appl. No.: 18/395,132

(22) Filed: Dec. 22, 2023

(51) Int. Cl. H01L 21/311; H01L 21/67

(52) U.S. Cl. CPC H01L 21/31116; H01L 21/67069; H01L 21/31144

(57) ABSTRACT

A method of etching larger critical dimension (CD) features and smaller CD features into a dielectric material through a single mask using an etch stop includes performing an inverse aspect-ratio dependent etching (ARDE) step that includes forming the etch stop on bottom surfaces of the larger CD features within the dielectric material using a first gas mixture, and etching the dielectric material within the smaller CD features using the first gas mixture while the etch stop prevents etching of the larger CD features. The method further includes performing an ARDE step that includes concurrently etching the dielectric material within the larger CD features at a first etch rate using a second gas mixture, and etching the dielectric material within the smaller CD features at a second etch rate slower than the first etch rate using the second gas mixture.

### TECHNICAL FIELD

The present invention relates generally to etching of dielectric materials, and, in particular embodiments, to systems and methods for etching features having multiple critical dimensions into a dielectric material through single mask using an etch stop.

### BACKGROUND

Microelectronic device fabrication typically involves a series of manufacturing techniques that include formation, patterning, and removal of a number of layers of material on a substrate. Etch masks may be formed (e.g., deposited, grown, patterned) to protect regions of the substrate and allow for pattern transfer via etching. Wet or dry etching processes may be used, with plasma etching processes being an example of a dry etching process. Etching processes that etch dielectric materials are often used to create electrical (e.g., conductive) connections between and within layers.

The size of features formed on a substrate can be defined in terms of the critical dimension (CD) of the feature. Features that have different CDs are often formed on the same substrate, and features with different CDs can be formed in the same layers of the substrate. Almost universally, larger CD features etch faster than smaller CD features (so-called aspect-ratio dependent etching (ARDE)). However, the desired etch depth may be any depth regardless of the CD size. Moreover, the same etch depth might be desired for larger CD features and smaller CD features. For this reason, it can be difficult or impossible to etch larger CD features and smaller CD features using a single mask, and separate masks are traditionally used for each CD.

Therefore, improved systems and methods for etching features that have different CDs into a dielectric material using a single mask are desirable.

### SUMMARY

In accordance with an embodiment of the invention, a method of etching larger CD features and smaller CD features into a dielectric material through a single mask using an etch stop includes performing an inverse ARDE step that includes forming the etch stop on bottom surfaces of the larger CD features within the dielectric material using a first gas mixture, and etching the dielectric material within the smaller CD features using the first gas mixture while the etch stop prevents etching of the larger CD features. The method further includes performing an ARDE step that includes concurrently etching the dielectric material within the larger CD features at a first etch rate using a second gas mixture, and etching the dielectric material within the smaller CD features at a second etch rate slower than the first etch rate using the second gas mixture.

In accordance with another embodiment of the invention, a method of reactive-ion etching (RIE) larger CD features and smaller CD features into a dielectric material through a single mask using an etch stop includes performing an inverse RIE-lag step that includes forming the etch stop on nitride bottom surfaces of the larger CD features within the dielectric material using a first gas mixture including fluorocarbon (CF) species and hydrofluorocarbon (CHF) species in a first ratio of CF to CHF, and etching the dielectric material within the smaller CD features using the first gas mixture while the etch stop prevents etching of the larger CD features. The method further includes performing an RIE-lag step that includes concurrently etching the dielectric material within the larger CD features at a first etch rate using a second gas mixture including CF species and CHF species in a second ratio of CF to CHF that is lower than the first ratio, and etching the dielectric material within the smaller CD features at a second etch rate slower than the first etch rate using the second gas mixture.

In accordance with still another embodiment of the invention, an etching system includes an etching chamber, a substrate support disposed in the etching chamber and configured to support a substrate including a dielectric material, a plurality of gas sources fluidically coupled to the etching chamber through a plurality of valves, and a controller operationally coupled to the plurality of valves. The controller includes a processor and a non-transitory computer-readable medium storing a program including instructions that, when executed by the processor, perform a method of etching larger CD features and smaller CD features into a dielectric material through a single mask using an etch stop. The method includes performing an inverse ARDE step that includes forming the etch stop on nitride bottom surfaces of the larger CD features within the dielectric material using a first gas mixture, and etching the dielectric material within the smaller CD features using the first gas mixture while the etch stop prevents etching of the larger CD features. The method further includes performing an ARDE step that includes concurrently etching the dielectric material within the larger CD features at a first etch rate using a second gas mixture, and etching the dielectric material within the smaller CD features at a second etch rate slower than the first etch rate using the second gas mixture.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example method of etching larger critical dimension (CD) features and smaller CD features into a dielectric material through a single mask using an etch stop in accordance with embodiments of the invention;

FIGS. 2A and 2B illustrate an example etching process that includes an inverse aspect ratio-dependent etch (ARDE) step and an ARDE step where FIG. 2A shows the inverse ARDE step when an etch stop is formed in larger CD features and FIG. 2B shows the ARDE step in accordance with embodiments of the invention;

FIGS. 3A and 3B illustrate an example etching process that includes an inverse ARDE step and an ARDE step where FIG. 3A shows the inverse ARDE step when an etch stop is formed in larger CD features and smaller CD features are etched to a desired endpoint and FIG. 3B shows the ARDE step when an additional etch stop is formed in the smaller CD features and the larger CD features are etched to a desired endpoint in accordance with embodiments of the invention;

FIGS. 4A, 4B, and 4C illustrate an example etching process that includes an inverse ARDE step, an additional inverse ARDE step, and an ARDE step where FIG. 4A shows the additional inverse ARDE step when an etch stop is formed in both larger CD features and intermediate CD features, FIG. 4B shows the inverse ARDE step when an etch stop is formed in only the larger CD features, and FIG. 4C shows the ARDE step in accordance with embodiments of the invention;

FIG. 5 illustrates an example etching system that includes an etching chamber within which etch processes including an inverse ARDE step when an etch stop is formed in larger CD features and an ARDE step may be performed in accordance with embodiments of the invention;

FIG. 6 illustrates an example method of etching larger CD features and smaller CD features into a dielectric material through a single mask using an etch stop in accordance with embodiments of the invention; and

FIG. 7 illustrates an example method of reactive-ion etching (RIE) larger CD features and smaller CD features into a dielectric material through a single mask using an etch stop in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Many etching processes, processes etch larger critical dimension (CD) features faster than smaller CD features (e.g., aspect ratio-dependent etching (ARDE) processes). For reactive-ion etching (RIE) processes, this phenomenon has been referred to as RIE-lag. The mechanism resulting in ARDE is largely due to the reduced flux of neutral species and ions to the etching front and increased interaction with the sidewall (which may produce shadowing effects). Conventionally, to etch features of different sizes, separate deposition, lithography and etch steps are required for each individual feature size.

For example, ARDE effects are a fundamental problem in plasma etching that leads to a large difference in etch rate of features of different sizes. For example, high aspect ratio contact (HARC) etching (such as dielectric HARC etches) using current hydrofluorocarbon (CHF)/fluorocarbon (CF) based chemistries tends to etch larger features much more rapidly, such as at etch rates more than 50% the etch rates of smaller features. Consequently, when simultaneously etching the larger and smaller features, substantial over-etch of the larger feature must occur in order to fully etch a smaller feature. This substantially degrades etching performance (e.g., resulting in etch defects in the larger features, such as sever bowing).

In highly polymer rich systems, larger CD features can experience slower etch rates than smaller CD features (an inverse ARDE process, or inverse RIE-lag process in the case of RIE) when passivating material (i.e., polymer) builds up faster on the etch front of larger CD features slowing the etch rate of the larger features. For example, limited lag control between larger CD features and smaller CD features has been contemplated when etching silicon oxide by repeating many etch cycle that alternate between an etchant gas exhibiting etch lag and a heavily polymerized etchant gas (e.g., using fluorocarbon-containing gas, O₂, and N₂ as the etch lag gas and then using hydrofluorocarbon-containing gas with a high hydrogen ratio, fluorocarbon-containing gas, a lower flow of O₂ and no N₂ as the heavily polymerized etchant gas).

However, conventional attempts to balance etch rate between larger CD features and smaller CD features have limited applicability since they require the etched material to be silicon oxide-based. Additionally, since both the larger CD features and the smaller CD features are both etched when using the heavily polymerized etchant gas, the amount of size difference between CDs is limited. The attainable difference between the etch rates of the larger CD features and the smaller CD features is also small, which imposes further limitations on the amount of size difference between CDs. Conventional techniques also use many etch cycles to control polymer build up which adds complexity and can reduce efficiency (e.g., because of additional interim steps used to switch between the etchant gases).

In accordance with various embodiments herein described, the invention proposes multi-step etching processes that can match the etch rate and over-etch amount in features with at least two different CD sizes (i.e., larger CD features and smaller CD features) etched into a dielectric material (e.g., including a nitride material). The multi-step etching processes include at least two steps: an inverse ARDE step (e.g., an inverse RIE-lag step) followed by an ARDE step (e.g., an RIE-lag step). During the inverse ARDE step, an etch stop is formed on bottom surfaces of the larger CD features using a first gas mixture (i.e., a full etch stop substantially preventing etching of the larger CD features using the first gas mixture). During the ARDE step, the dielectric material within both the larger CD features and the smaller CD features is etched concurrently using a second gas mixture. The etch rate of the larger CD features is greater than the etch rate of the smaller CD features (thereby allowing the larger CD features to catch-up to the smaller CD features). The first gas mixture may include CF species and CHF species in a first CF:CHF ratio while the second gas mixture may also include CF species and CHF species in a second CF:CHF ratio that is lower than the first ratio.

The proposed multi-step etching processes use a full etch stop during an inverse ARDE step, whereas conventional attempts to balance etch rate between larger CD features and smaller CD features only slow the etching of the larger CD features. Additionally, the proposed multi-step process can be used to etch dielectric materials that include a nitride material (as opposed to conventional techniques, which only apply to silicon oxide etches).

During the inverse ARDE step, an etch stop does not form on the smaller CD features (e.g., features with a smaller top CD than the top CD of the larger CD features) and they are etched a desired depth without substantial etching of the larger CD features. Because the etch stop substantially prevents all etching of the larger CD features, the difference in etch depth may be advantageously large. That is, once the etch stop is formed on the larger CD features (e.g., early in the inverse ARDE step), the smaller CD features may be etched for as long as desired without etching the larger CD features.

During the ARDE step, the larger CD features etch faster than the smaller CD features and the final difference between the etch depths can be tuned. For example, in many cases it may be desirable for the etch depths to substantially match (to allow the features to connect with the same underlying layer without undesirable over-etching).

For some applications, the chemistry of the second gas mixture used in the ARDE step may have some negative impact on the etch profile of the smaller CD features. Therefore, it may be advantageous for the ARDE step to be as short as possible. Because the smaller CD features may be etched to any desired depth during the inverse ARDE step, the chemistry of the second gas mixture may be chosen to etch the larger CD features much faster than the smaller CD features, which reduces duration of the ARDE step and may have the benefit of providing high-quality etch profiles. In contrast, conventional methods must account for the depth that larger CD features are etched using a heavily polymerized etchant gas, limiting the flexibility of an etch lag gas and potentially reducing the quality of the etch profiles.

A further possible benefit of using a full etch stop is the ability to land to differently sized features simultaneously using as little as two steps (e.g., with only two feature sizes only a single inverse ARDE step and a single ARDE step may be needed). Further, the chemistry of the first gas mixture may be tuned to form an etch stop in the larger of two features with any CD size while etching the smaller of the two features. For example, in the case of mixtures containing CF and CHF species, the CF:CHF ratio may be tuned to form an etch stop on the larger CD features and not the smaller CD features, even when the ratio between the CD size is large (e.g., as much as 10:1 or even higher).

There may also be advantages to including nitride in the dielectric layer. For example, compared to silicon oxide, silicon nitride builds up a thicker polymer layer under dielectric etching conditions. This polymer layer thickness is highly dependent on the quantity of reactive neutrals that can reach the etching front, which is an aspect ratio dependent phenomena. The ability to build up polymer quickly on nitride may be advantageously leveraged to quickly form an etch stop and to form the etch stop so that it substantially prevents etching of the larger CD features during the inverse ARDE step. Further, many structures (such as 3D NAND structures) use ONO stacks, making compatibility with nitride-containing dielectric materials advantageous.

The multi-step etching processes may also advantageously reduce the number of required etching steps and cost during manufacturing by integrating previously separate etch steps together. Common CF and CHF gases can also be used, which may reduce the cost and complexity of implementing the multi-step etching processes in existing tools and systems.

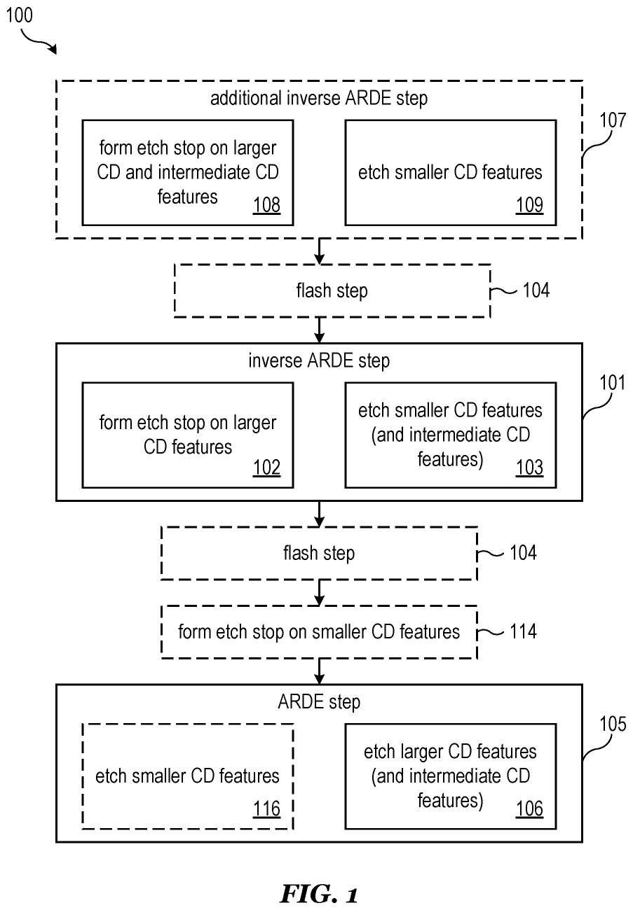

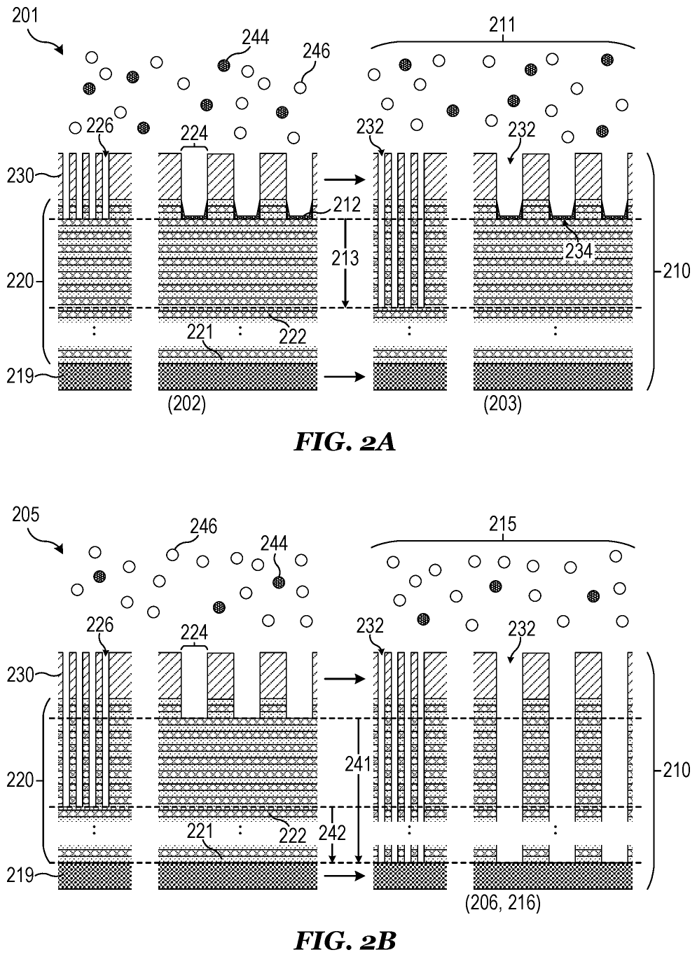

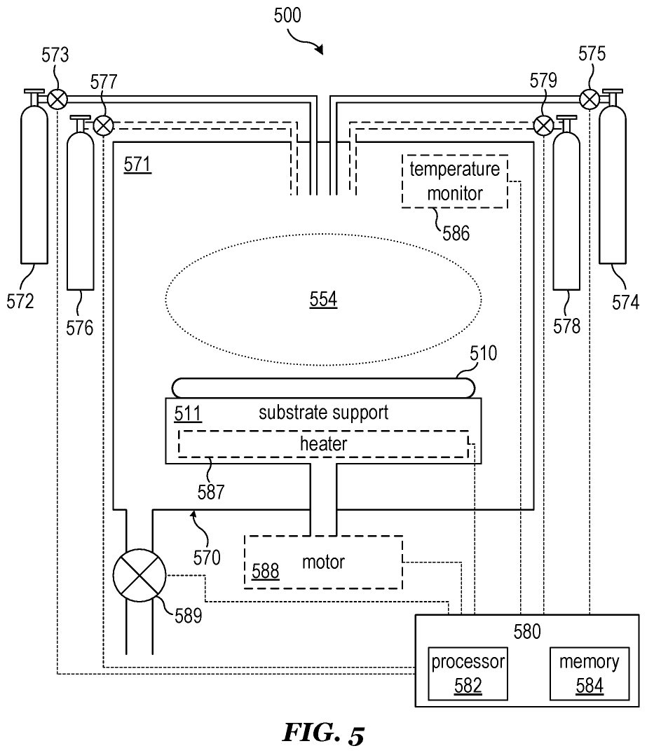

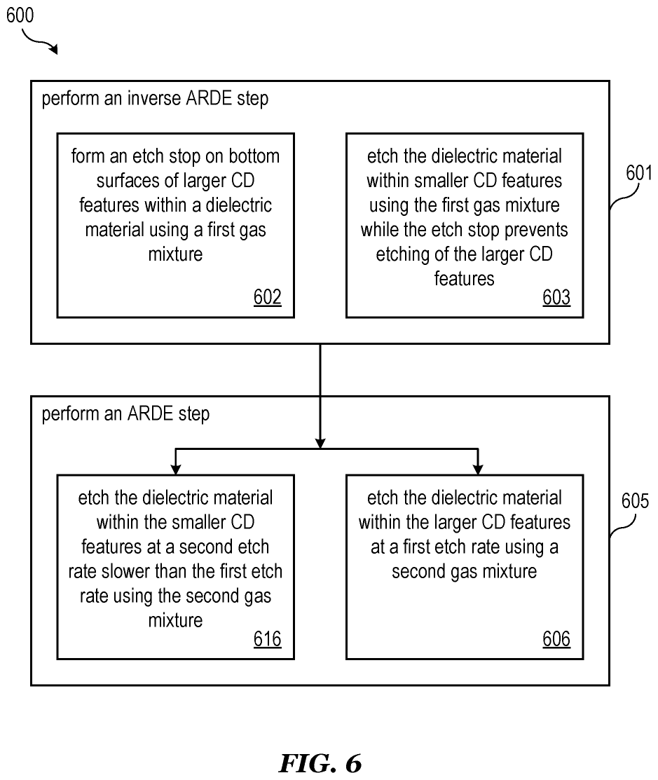

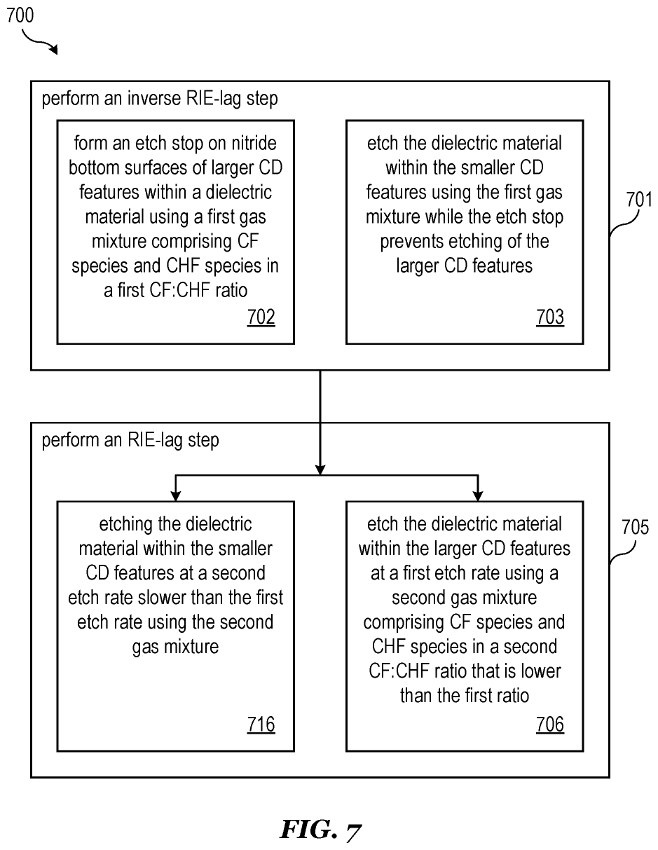

Embodiments provided below describe various methods and systems for etching of dielectric materials, and in particular, to methods and systems for etching features having multiple critical dimensions into a dielectric material through a single mask using an etch stop. The following description describes the embodiments. FIG. 1 is used to describe an example method of etching a dielectric material while FIGS. 2A-2B, 3A-3B, and 4A-4C are used to described three example etching processes. An example etching system that can be used to perform the methods is described using FIG. 5. Two more example methods are described using FIGS. 6 and 7.

FIG. 1 illustrates an example method of etching larger CD features and smaller CD features into a dielectric material through a single mask using an etch stop in accordance with embodiments of the invention.

Referring to FIG. 1, a method 100 of etching (e.g., RIE etching) larger CD features and smaller CD features (at least two different CD sizes in the same pattern) into a dielectric material (oxide, nitride, oxynitride, etc., including multiple layers, such as an ONO stack) through a single mask (e.g., a hardmask, such as an amorphous carbon layer (ACL) mask, a metal hardmask (MHM), and others) using an etch stop (e.g., deposited material, such as polymer) includes an inverse ARDE step 101 (e.g., an inverse RIE-lag step) and an ARDE step 105 (e.g., an RIE-lag step). The inverse ARDE step 101 includes an etch stop formation process 102 during which the etch stop is formed in the larger CD features within the dielectric material (e.g., on bottom surfaces of the larger CD features). The etch stop in the larger CD features prevents etching of larger CD features while the dielectric material within the smaller CD features is etched during an inverse ARDE etching process 103 of the inverse ARDE step 101.

Both the etch stop formation process 102 and the inverse ARDE etching process 103 use the same chemistry (e.g., a first gas mixture supplied during the inverse ARDE step 101). That is, the first gas mixture is used to form the etch stop and is also used to etch the dielectric material in the smaller CD features. Once the first gas mixture is provided, the exposed dielectric material within the smaller CD features begins to be etched. The etch stop may form substantially instantly once the first gas mixture is provided or there may be some amount of time before the etch stop forms. For example, the dielectric material within the larger CD features may initially be etched by the first gas mixture (e.g., slower and slower) until the etch stop is formed.

Although the first gas mixture is used during both the etch stop formation process 102 and the inverse ARDE etching process 103, the chemistry is not required to remain the same for the entirety of the inverse ARDE step 101. For example, after the etch stop is formed, it may be advantageous to alter the chemistry of the first gas mixture (e.g., forming another gas mixture, multiple new gas mixtures as the inverse ARDE etching process 103 proceeds, or dynamically changing the chemistry during the inverse ARDE etching process 103). One possible reason to change the etch chemistry after the etch stop is formed is to improve the etch profile of the smaller CD features. In this situation, the changes made to the first gas mixture may be selected to improve various aspects relating to the etching of the smaller CD features (e.g., high aspect ratio (HAR) features) while maintaining the etch stop that has already been formed in the larger CD features.

The ARDE step 105 includes an ARDE etching process step 106 during which the dielectric material within the larger CD features is etched. A second gas mixture is used during the ARDE step 105 (i.e., different than the first gas mixture used in the inverse ARDE step 101). The second gas mixture is selected so that the etching process is an ARDE process, which etches the larger CD features faster than the smaller CD features. That is, the etch rate of the smaller CD features during the ARDE step 105 is slower than the etch rate of the larger CD features. The second gas mixture may etch the dielectric material within the smaller CD features so that the ARDE step 105 includes a smaller CD ARDE etching process 116 (i.e., the dielectric material within both the larger CD features and the smaller CD features is etched concurrently using the second gas mixture). Alternatively, the etch rate of the smaller CD features during the ARDE step 105 may be substantially zero.

One specific example of when the etch rate of the smaller CD features is substantially zero during the ARDE step 105 is when an additional etch stop is formed during an optional etch stop formation process 114. For example, openings of the mask corresponding to the smaller CD features may be closed (e.g., clogged) to form the additional etch stop. In this method of forming the additional etch stop, the increased size of the larger CD features may prevent clogging from occurring, advantageously resulting in an etch stop being preferentially formed in the smaller CD features. The second gas mixture may be used during the optional etch stop formation process 114 (e.g., the optional etch stop formation process 114 may be part of the ARDE step 105, similar to the etch stop formation process 102 being a part of the inverse ARDE step 101). The optional etch stop formation process 114 may also be performed using different chemistry before the ARDE step 105.

A potential advantage of including the optional etch stop formation process 114 is to allow the smaller CD features to be fully etched during the inverse ARDE step 101 which may avoid possible negative side effects to the etch profile of the smaller CD features when etching the larger CD features in the ARDE step 105. For example, during the inverse ARDE step 101, the dielectric material within the smaller CD features may be etched until a desired endpoint is reached, whether the endpoint is desired etch depth or reaching a desired layer, such as an underlying layer. Because the additional etch stop prevents etching of the smaller CD features during the ARDE step 105, the larger CD features can be etched completely independently from the smaller features using the single mask. This has the benefit of allowing the chemistry of the second gas mixture to be chosen without regard for the etch profile of the smaller CD features.

In some embodiments, etch stops that are formed during the method 100 may be removed using the chemistry of a subsequent step (e.g., the ARDE step 105 may remove the etch stop formed on the larger CD features, etc.). However, in some cases, a specific chemistry may be used to remove etch stops, which may be thought of as a separate step in the method 100. For example, an optional flash step 104 may be included at various points in the method 100 to selectively remove etch stops from the dielectric material and the mask (e.g., also referred to or considered a polymer removal step, de-clogging step, etc.). The optional flash step 104 may include a different chemistry than other steps in in the method 100 (e.g., a flash gas mixture including oxygen, such as including O₂ as part of a plasma).

So far, the method 100 has been described from the perspective of etching two differently-sized features (the smaller CD features and the larger CD features). However, the method 100 is generalizable to etch patterns with more than two CD sizes using a single mask. For example, to etch three differently-sized features (i.e., smaller CD features, intermediate CD features, and larger CD features) an additional inverse ARDE step 107 may be included (e.g., before or after the inverse ARDE step 101). Similar to the inverse ARDE step 101, the additional inverse ARDE step 107 also includes an etch stop formation process 108 and an inverse ARDE etching process 109.

Because the smaller CD features etch faster than the intermediate CD features during an ARDE etching process, the goal of the additional inverse ARDE step 107 is to form an etch stop on both the intermediate CD features and the larger CD features during the etch stop formation process 108 so that only the smaller CD features are etched during the inverse ARDE etching process 109. For example, an intermediate etch stop may be formed on bottom surfaces of intermediate CD features and on bottom surfaces of the larger CD features using a third gas mixture (i.e., having a different chemistry than both the first gas mixture and the second gas mixture so that an etch stop will form in the intermediate CD features and the larger CD features whereas the first gas mixture only forms an etch stop in the larger CD features) while the smaller CD features are etched by the third gas mixture (initially or entirely as previously discussed).

The additional inverse ARDE step 107 results in a difference in the etch depth of the smaller CD features relative to the intermediate CD features and the larger CD features. In the inverse ARDE step 101, both the smaller CD features and the intermediate CD features may be etched by the first gas mixture. This results in a difference in etch depth between the intermediate CD features and the larger CD features, as well as potentially further differences between the intermediate CD features and the smaller CD (e.g., because the inverse ARDE etching process 103 is inversely dependent on aspect ratio).

Because the inverse ARDE step 101 and the additional inverse ARDE step 107 include an inverse ARDE etching process, the first gas mixture may have some similarity to the third gas mixture (e.g., more similarity than to the second gas mixture). However, the distinct chemistry of the third gas mixture is chosen so that the smallest CD size that will form an etch stop is lower than for the first gas mixture. Of course, this concept can be extended to more than three CD sizes, subject to practical considerations specific to a given application.

The various steps of the method 100 may be performed in the order provided in FIG. 1 as an example. However, the steps may be performed in any suitable order or concurrently with one another. For instance, when included, the additional inverse ARDE step 107 may be performed after the inverse ARDE step 101. The steps may also be repeated as part of a cycle in some cases. Further, the processes making up each of the steps may also be performed serially, concurrently, or repeated as part of a cycle. Additional steps may also be added (whether related to the method 100 or performed during the method 100 for other reasons).

As one specific example, one might envision an implementation of the method 100 where it is desirable to etch each of the three CD sizes exclusively of one another using a single mask. The additional inverse ARDE step 107 may be performed first to etch the smaller CD features followed by a flash step 104 to remove the etch stop from the intermediate CD features (and the larger CD features) and a smaller CD etch stop formation process 114 to clog openings of the smaller CD features. The inverse ARDE step 101 may then be performed to etch only the intermediate CD features (because an etch stop was formed in the smaller CD features by clogging the openings). Another flash step 104 may remove the etch stop from the larger CD features (which may or may not unclog the smaller CD features). Another smaller CD etch stop formation process 114 may then be performed to clog both the smaller CD features and the intermediate CD features (e.g., with a longer duration and/or different chemistry than the first smaller CD etch stop formation process 114). The ARDE step 105 may then be performed to etch only the larger CD features.

As another specific example, the etch stops might be formed in the largest CD features first, and then continue in order towards the smallest CD features, perhaps to avoid multiple flash steps. In this situation, the inverse ARDE step 101 might be performed first, then one or more additional inverse ARDE steps 107 might be performed, and a single flash step 104 (or no flash step) may be performed before the ARDE step 105 is performed. Of course, an optional smaller CD etch stop formation process 114 may be included before the ARDE step 105 as well.

The method 100 may be performed using an etching system. For example, each of the steps of the method 100 may be performed in an etching chamber (e.g., a plasma etching chamber) of an etching system. The etching system may have a substrate support disposed in the etching chamber that is configured to support a substrate that includes the dielectric material. A plurality of gas sources may be fluidically coupled to the etching chamber through a plurality of valves, and a controller may be operationally coupled to the plurality of valves so that gases may be supplied to the etching chamber to form the various mixtures of gases used by the method 100. The controller may include a processor and a non-transitory computer-readable medium storing a program including instructions that, when executed by the processor, perform the method 100.

Utilizing chemistry that demonstrates inverse ARDE effects (e.g., inverse RIE-lag) followed by chemistry demonstrating ARDE (e.g., RIE-lag) can advantageously allow control over the relative etch depths of differently-sized features of the same pattern using a single mask. For example, both smaller CD features (e.g., on the order of tens of nanometers, such as about 70 nm) and larger CD features (e.g., on the order of hundreds of nanometers, such as about 400 nm) can land simultaneously and have etch profiles with good quality. At least two separate chemistries are utilized, with one (in the inverse ARDE step 101) intentionally stopping the etching of larger CD features, and another (in the ARDE step 105) etching larger CD features faster than smaller CD features to achieve the desired etch depths. In this way, simultaneous etching of different CD regions in a sample may be achieved even when the CD ratio is large. (e.g., 4:1, 10:1, or even higher) because the total etch rate of the different CD regions can be matched.

Various mechanisms may be used to control the relative etch rates of the difference CD sizes. For example, a larger CD may allow for more polymer-causing neutrals to diffuse to the etch front, (e.g., as opposed to impacting a sidewall or mask surface) compared to a smaller CD. than would occur in a smaller CD feature. These neutrals may form polymer at the etch front of the larger CD features (e.g., bottom surfaces of the larger CD features), but not the smaller CD features. For this reason, one possible difference between the ARDE gas mixture and the inverse ARDE gas mixture (and additional inverse ARDE gas mixtures) is that inverse ARDE gas mixtures may have a higher proportion of polymer-causing neutrals.

Conventional techniques may result in over-etching larger CD features due to ARDE effects. Since the timing of completing the etching of larger CD features can be controlled in the method 100, a better etch profile is achieved (e.g., lower bowing in the larger CD features due to decreased over-etch amount). Process steps may advantageously be avoided by using a single mask to etch multiple CD sizes (e.g., when the lithography is optimized to pattern the multiple CD sizes), which may have the benefit of increasing throughput.

FIGS. 2A and 2B illustrate an example etching process that includes an inverse aspect ratio-dependent etch (ARDE) step and an ARDE step where FIG. 2A shows the inverse ARDE step when an etch stop is formed in larger CD features and FIG. 2B shows the ARDE step in accordance with embodiments of the invention. The etching process of FIGS. 2A and 2B may include specific implementations of methods described herein such as the method of FIG. 1, for example. Similarly labeled elements may be as previously described.

Referring to FIG. 2A, the etching process includes an inverse ARDE step 201 during which a first gas mixture 211 is used to form an etch stop 212 in larger CD features 224 and to etch dielectric material 220 within smaller CD features 226. It should be noted that here and in the following a convention has been adopted for brevity and clarity wherein elements adhering to the pattern [x01] where ‘x’ is the figure number may be related implementations of an inverse ARDE step in various embodiments. For example, the inverse ARDE step 201 may be similar to the inverse ARDE step 101 except as otherwise stated. An analogous convention has also been adopted for other elements as made clear by the use of similar terms in conjunction with the aforementioned numbering system.

The dielectric material 220 may be included as part of a substrate 210 (e.g., supported by an underlying layer 219, which may be a semiconductor layer, such as a device layer, of a wafer, for example). The substrate 210 may be any suitable substrate, such as an insulating, conducting, or semiconducting substrate with one or more layers disposed thereon. For example, the underlying layer 219 of the substrate 210 may be a semiconductor wafer, such as a silicon wafer, and include various layers, structures, and devices (e.g., forming integrated circuits). In one embodiment, the underlying layer 219 includes silicon. In another embodiment, the underlying layer 219 includes silicon germanium (SiGe). In still another embodiment, the underlying layer 219 includes gallium arsenide (GaAs). Of course, many other suitable materials, semiconductor or otherwise, may be included in the underlying layer 219 as may be apparent to those of skill in the art.

The dielectric material 220 may be any suitable material or combination of materials. In various embodiments, the dielectric material 220 includes an oxide material, and the dielectric material 220 includes silicon dioxide (SiO₂) in one embodiment, and includes tetraethyl orthosilicate (TEOS) in one embodiment. In some embodiments, the dielectric material 220 includes a nitride material, and the dielectric material 220 includes silicon nitride (Si₃N₄) in one embodiment. Of course, other classes of dielectric material may also be included in the dielectric material 220, such as an oxynitride material (e.g., silicon oxynitride (SiOₓN_{y}), and others).

The dielectric material 220 may include more than one type of material (even including materials not necessarily acting as or classified as dielectric materials so long as the dielectric material 220 may be selectively etched. In some specific applications, such as HARC etches, the dielectric material 220 may be a stack of several layers of dielectric material. One specific example is an ONO stack, which includes a multiple oxide layers 221 (e.g., SiO₂) separated by nitride layers 222 (e.g., Si₃N₄), as shown.

A mask 230 overlies the dielectric material 220 and includes openings 232 that are configured to be used to etch a desired pattern into the dielectric material 220. The mask 230 may be any suitable mask that is configured to protect regions of the dielectric material 220 while allowing the dielectric material 220 to be etched through the openings 232 during the etching process. In various embodiments, the mask 230 is a hardmask, such as an ACL or an MHM (metal hardmask). The mask 230 may be electrically conductive, semiconducting, or insulating.

The inverse ARDE step 201 includes an etch stop formation process 202 during which the etch stop 212 is formed in the larger CD features 224 (e.g., on bottom surfaces 234) using first gas mixture 211. While the first gas mixture 211 may include any number of types of species in various ratios, the first gas mixture 211 includes a first species 244 and a second species 246 in various embodiments. For example, the first species 244 may include fluorocarbon (CF) species (having the formula CₓF_{y}) while the second species 246 may include hydrofluorocarbon (CHF) species (having the formula CₓH_{z}F_{y}). In some embodiments, the first species 244 includes one or more higher order CF species (e.g., CₓF_{y} where x is at least 2, such as C₄F₆, C₄F₈, etc.). In one embodiment, the second species 246 includes trifluoromethane (e.g., CHF₃, also referred to as fluoroform). Of course, other gases may also be included, such as unreactive gases (e.g., noble gases, such as helium, argon, neon, krypton, etc.) and reactive gases (e.g., oxygen-containing gases, such as O₂, nitrogen-containing gases, such as NH₃, other halogen-containing gases, etc.).

In certain etching environments including nitride in the dielectric material 220 may facilitate the formation of an etch stop (e.g., in contrast to merely slowing the etch rate of larger CD features). For example, for polymer-forming etchants such as CF gases and CHF gases, polymer may build up on nitride material faster than other materials, such as oxide. Of course, whether an advantage is obtained for any given aspect of the dielectric material 220 will depend on the specifics of a particular implementation of the etching process. However, when nitride serves as a preferential substrate for etch stop formation, the etching process may be advantageous for use in etching nitride-containing dielectric layers, such as silicon nitride, an ONO stack, and the like.

The inverse ARDE step 201 also includes an inverse ARDE etching process 203, during which the first gas mixture 211 is used to etch the dielectric material 220 in the smaller CD features 226 while the etch stop 212 prevents etching of the larger CD features 224. As shown here, the etch stop 212 may form on the bottom surfaces 234 (e.g., on nitride bottom surfaces) of the larger CD features 224 quickly (e.g., substantially immediately once the first gas mixture 211 is provided or very soon thereafter) and the smaller CD features 226 may be etched to an inverse ARDE etch depth 213 while the etch front in the larger CD features 224 is protected.

The smaller CD features 226 may be etched to any desired inverse ARDE etch depth 213, so long as it is deeper than the etch stop 212. In some cases, such as when an additional etch stop formation process is used to prevent etching of the smaller CD features 226, the inverse ARDE etch depth 213 may extend all the way to the underlying layer 219 (or even beyond if so desired).

Referring now to FIG. 2B, the etching process also includes an ARDE step 205 during which a second gas mixture 215 is used to etch the dielectric material 220 within both the larger CD features 224 and the smaller CD features 226. Specifically, the ARDE step 205 includes an ARDE etching process 206 that etches the larger CD features 224 at a first etch rate 241 and a smaller CD ARDE etching process 216 that etches the smaller CD features 226 at a second etch rate 242. As shown, the second etch rate 242 is slower (it can even be substantially zero, as previously discussed) than the first etch rate 241 so that the difference in the etch depths of the larger CD features 224 and the smaller CD features 226 is decreased.

Although not necessarily required, the second gas mixture 215 may include the same (or similar categories) of species, as demonstrated in this specific example. For example, the second gas mixture 215 may include the first species 244 and the second species 246, but in a different ratio. In implementations where the first species 244 includes CF species and the second species 246 includes CHF species, the difference between the first gas mixture 211 and the second gas mixture 215 may be the ratio between the CF species and the CHF species (CF:CHF ratio).

In various embodiments, the CF:CHF ratio of the first gas mixture 211 is higher than the CF:CHF ratio of the second gas mixture 215. In some embodiments, the CF:CHF ratio of the first gas mixture 211 is greater than about 0.45 and is about 0.48 in one embodiment. In contrast, the CF:CHF ratio of the second gas mixture 215 is less than about 0.25 in some embodiments, and is about 0.23 in one embodiment. As already mentioned, either of the first species 244 and the second species 246 may be a category of compounds, such as CF species or CHF species, for example. This may be leveraged to provide further tuning of the chemistry for the gas mixtures, such as by including more than one type of CF species (e.g., C₄F₆ and C₄F₈) or CHF species, for this specific example. In some cases, the chemistry of the first gas mixture 211 may be altered during the inverse ARDE etching process 203 (e.g., after the etch stop 212 is formed). For example, a third gas mixture may be used that has a different ratio than the first gas mixture 211. Continuing the example, above, the third gas mixture may have a CF:CHF ratio between than of the first gas mixture 211 and the second gas mixture 215.

Of course, independent of the specific chemistry involved, the exact ratios may depend on a variety of factors related to the specific implementation. For example, the ability to selectively form an etch stop larger CD features may depend on the dimensionality of the larger CD features, the composition of the dielectric material 220, and other factors. Moreover, the CD size difference between features may also impact the ratios. The CD size difference between one or more CDs may relatively large, which may advantageously be made possible because of the formation of a full etch stop. In various embodiments, the CD ratio between the larger CD features and the smaller CD features is greater than 4:1, and is greater than about 10:1 in some embodiments. As a specific example, the smaller CD features may have a CD of about 70 nm while the larger CD features may have a CD of about 400 nm. Of course, these are merely examples, since a potential advantage of the etching process is the flexibility to control the relative etch rates of multiple CDs of any relative size.

For a given CD size, an upper threshold for the CF:CHF ratio may indicate the approximate point above which the etch stop 212 will form while a lower threshold may indicate the approximate point below which no etch stop will form. In between, the behavior may transition from an etch stop forming regime to a non-etch stop forming regime. For instance, for some CD size, the upper threshold may be about 0.45 indicating that the formation of a full etch stop is substantially guaranteed (e.g., 95% for a given process) while the lower threshold may be about 0.25 indicating that there is substantially no chance to of etch stop (e.g., <5% chance of full etch stop). Then, a CF:CHF ratio of about 0.7, being above the upper threshold would result in a full etch stop (with even more likelihood than 0.45) while a CF:CHF ratio of about 0.15 may have no etch stop.

While the specific mixture of gases may depend on a given application, one specific gas mixture example includes C₄F₆, C₄F₈, CHF₃, and O₂. In this implementation, the first species 244 are CF species and include C₄F₆ and C₄F₈ while the second species 246 are CHF species and includes CHF₃). The O₂ gas may be included as an additional gas (and of course other gases could be included). The first gas mixture 211 used during the inverse ARDE step 201 may include C₄F₆/C₄F₈/CHF₃/O₂ provided at flowrates of about 95/40/280/90 SCCM (standard cubic centimeters per minute) corresponding to a CF:CHF ratio of about 0.48 while the second gas mixture 215 used during the ARDE step 205 may include C₄F₆/C₄F₈/CHF₃/O₂ provided at flowrates of about 50/21/305/80 SCCM corresponding to a CF:CHF ratio of about 0.23.

In keeping with the above discussion, the CF:CHF ratio of 0.48 during the inverse ARDE step 201 may cause the etch stop 212 to form in the larger CD features 224 (e.g., features with a 400 nm CD) while allowing continuous etching in the smaller CD features 226 (e.g., features with a 70 nm CD). Additional steps may also be included, such as a short etching step with higher CF flow before the inverse ARDE step 201 to ensure etch stop in the 400 nm feature. For example, this would be an example of a first gas mixture being used at the beginning of the inverse ARDE step 201 and another gas mixture being used after the etch stop 212 is formed.

A short O₂ flash step may also be added to remove excessive polymer buildup on the etch front and ensure that the ARDE step 205 can being etching both features simultaneously (that is, it may not be necessary because the polymer in the new etch chemistry may still be etched away without the flash step, but the flash step may be included in order to enhance the control over the starting point for the etching of all features in the ARDE step 205).

The second gas mixture 215 is chosen so that the larger CD features etch at a faster rate than the smaller features, allowing for the larger CD feature to catch up to the smaller cd features. In some cases, the second gas mixture 215 may be chosen so that the difference is etch rates is relatively large, which may have the benefit of avoiding damage to the etch profile of the smaller CD features during the ARDE step 205. After completion of both the inverse ARDE step 201 and the ARDE step 205 the etch depths of the larger CD features and the smaller CD features should be at the desired positions relative to one another (e.g., both steps may be at a substantially similar etch depth, such as at the underlying layer 219, as shown).

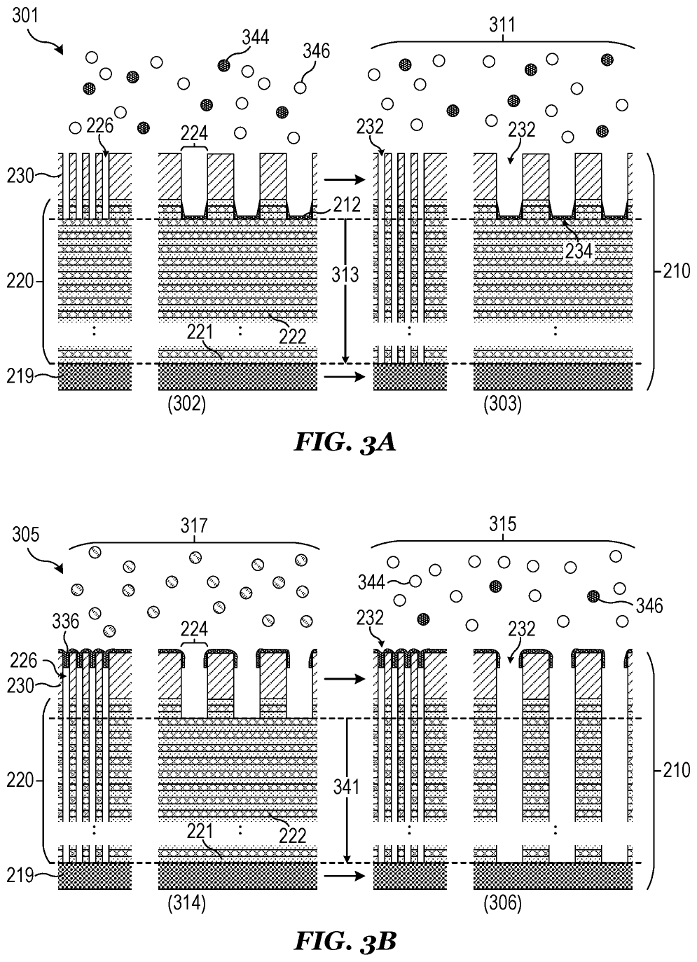

FIGS. 3A and 3B illustrate an example etching process that includes an inverse ARDE step and an ARDE step where FIG. 3A shows the inverse ARDE step when an etch stop is formed in larger CD features and smaller CD features are etched to a desired endpoint and FIG. 3B shows the ARDE step when an additional etch stop is formed in the smaller CD features and the larger CD features are etched to a desired endpoint in accordance with embodiments of the invention. The etching process of FIGS. 3A and 3B may be a specific implementation of other etching processes described herein such as the etching process of FIGS. 2A and 2B, for example. Similarly labeled elements may be as previously described.

Referring to FIGS. 3A and 3B, the etching process includes an inverse ARDE step 301 during which a first gas mixture 311 (e.g., including a first species 344 and a second species 346) is used to form an etch stop etch stop 212 in larger CD features 224 and to etch dielectric material 220 within smaller CD features 226. The inverse ARDE step 301 includes an etch stop formation process 302 and an inverse ARDE etching process 303. The etching process further includes an ARDE step 305 that includes an ARDE etching process 306 during which a second gas mixture 315 (e.g., including a different chemistry than the first gas mixture 311, such as the first species 344 and the second species 346 in a different ratio) is used to etch the larger CD features 224.

In contrast to the ARDE step 205 discussed in reference to FIG. 2B, the ARDE step 305 of FIG. 3B also includes an optional smaller CD etch stop formation process 314 during which an additional etch stop 336 is formed in the smaller CD features 226 using an additional gas mixture 317 (which is different than the first gas mixture 311 and may be different than the second gas mixture 315). For example, the additional etch stop 336 may be polymer build up that occurs at the tops of the openings 232 of the smaller CD features 226 (as opposed to bottom surfaces 234), and forms a complete etch stop, such as by clogging the smaller CD features 226. For example, the gas mixture 317 may include one or more gases that may promote polymer growth (when provided with the appropriate conditions), such as difluoromethane (CH₂F₂), fluoromethane (CH₃F), methane (CH₄), and others. For example, various CₓF_{y} gases provided with limited O₂ may also be used.

Because the additional etch stop 336 operates as a full etch stop, an inverse ARDE etch depth 313 may proceed all the way to an endpoint in the inverse ARDE step 301, such as to the underlying layer 219, as shown. In the ARDE step 305, the smaller CD features 226 is not etched and the larger CD features 224 are etched at a larger CD etch rate 341 that proceeds all the way to the desired endpoint for the larger CD features 224 (such as the underlying layer 219, as shown). For example, the use of the additional etch stop 336 in the ARDE step 305 may correspond with a specific implementation of ARDE step 205 where the second etch rate 242 (of the smaller CD features) is substantially zero.

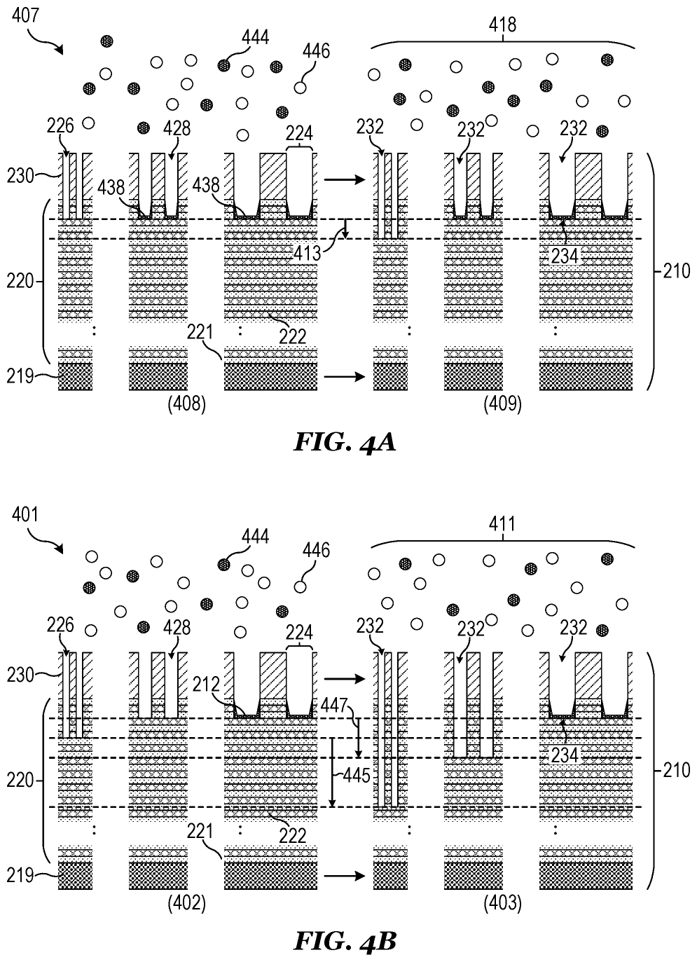

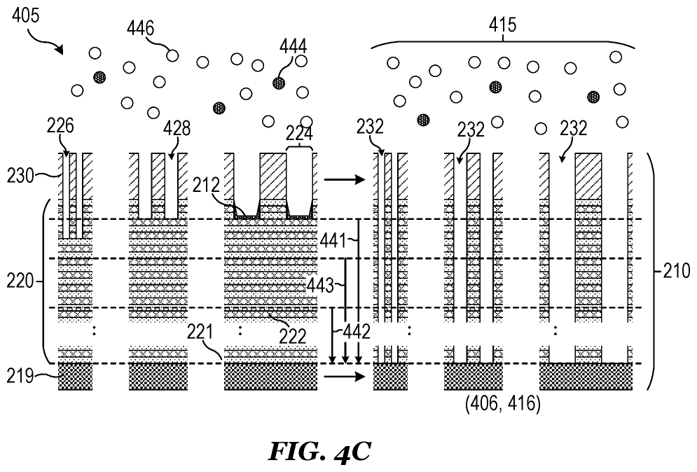

FIGS. 4A, 4B, and 4C illustrate an example etching process that includes an inverse ARDE step, an additional inverse ARDE step, and an ARDE step where FIG. 4A shows the additional inverse ARDE step when an etch stop is formed in both larger CD features and intermediate CD features, FIG. 4B shows the inverse ARDE step when an etch stop is formed in only the larger CD features, and FIG. 4C shows the ARDE step in accordance with embodiments of the invention. The etching process of FIGS. 4A, 4B and 4C may be a specific implementation of other etching processes described herein such as the etching process of FIGS. 2A and 2B, for example. Similarly labeled elements may be as previously described.

Referring to FIGS. 4A-4C, the etching process includes an inverse ARDE step 401 during which a first gas mixture 411 (e.g., including a first species 444 and a second species 446) is used to form an etch stop etch stop 212 in larger CD features 224 and to etch dielectric material 220 within smaller CD features 226. The inverse ARDE step 401 includes an etch stop formation process 402 and an inverse ARDE etching process 403. The etching process further includes an ARDE step 405 that includes an ARDE etching process 406 during which a second gas mixture 415 (e.g., including a different chemistry than the first gas mixture 411, such as the first species 444 and the second species 446 in a different ratio) is used to etch the larger CD features 224.

In addition to the inverse ARDE step 401 and the ARDE step 405, an additional inverse ARDE step 407 (FIG. 4A) is also included in the etching process. The additional inverse ARDE step 407 includes an etch stop formation process 408 during which an intermediate etch stop 438 is formed both in intermediate CD features 428 and the larger CD features 224 using a third gas mixture 418 that has different chemistry than the first gas mixture 411 and the second gas mixture 415. For example, the third gas mixture 418 may have the first species 444 and the second species 446 in still another ratio (although the species may also be different or species may also be included). In various embodiments, the third gas mixture 418 has the first species 444 and the second species 446 in a higher ratio than the first gas mixture 411.

The additional inverse ARDE step 407 also includes an inverse ARDE etching process 409 that etches the smaller CD features 226 (and not the intermediate CD features 428 or the larger CD features 224) to an inverse ARDE etch depth 413 (i.e., to generate a difference in the etch depth between the smaller CD features 226 and the intermediate CD features 428). Meanwhile, the etch stop 212 is not formed in the intermediate CD features 428 during the etch stop formation process 402, and so both the smaller CD features 226 and the intermediate etch stop 438 are etched during the etch stop formation process 402 of inverse ARDE step 401. This, results in further differentiation between the etch depths, such as inverse ARDE smaller CD etch depth 445 and inverse ARDE intermediate CD etch depth 447 shown in FIG. 4B.

In the ARDE step 405, all three of the CD sizes (the larger CD features 224, the intermediate CD features 428, and the smaller CD features 226) are etched during the inverse ARDE etching process 403 and the smaller CD ARDE etching process 416 (unless an etch stop is formed on the smaller CD features 226, similar to previously described optional steps). Rather than two etch rates (as shown in the ARDE step 205 of FIG. 2B, for example), the ARDE step 405 has three etch rates, a first etch rate 441 of the larger CD features 224, second etch rate 442 of the smaller CD features 226, and a third etch rate 443 of the intermediate CD features 428, which is between the first etch rate 441 and the second etch rate 442.

FIG. 5 illustrates an example etching system that includes an etching chamber within which etch processes including an inverse ARDE step when an etch stop is formed in larger CD features and an ARDE step may be performed in accordance with embodiments of the invention. The etching system of FIG. 5 may be used to perform any of the example etching processes described herein such as the etching process of FIGS. 2A and 2B, for example. Similarly labeled elements may be as previously described.

Referring to FIG. 5, an etching system 500 (e.g., a plasma etching system, such as an RIE etching system) includes a substrate support 511 disposed within an etching chamber 571 and configured to support a substrate 510. A first species gas source 572 (e.g., a CF gas source) and a second species gas source 574 (e.g., a CHF gas source) are fluidically coupled to the etching chamber 571 through a first species valve 573 and a second species valve 575 respectively. Additional gas sources and valves may also be included in the etching system 500. For example, an optional additional gas source 576 may be fluidically coupled to the etching chamber 571 through an optional additional gas valve 577 (an additional gas may be any type of gas, and multiple additional gases may be included) while an optional carrier gas source 578 may be fluidically coupled to the etching chamber 571 through an optional carrier gas valve 579. An exhaust valve 589 is included to evacuate the etching chamber 571 during the etching process.

The etching system 500 may be configured to generate a plasma 554 during any or all of the steps of an etching process (e.g., during a plasma etching process, such as an RIE process). The etching chamber 571 may be any suitable etching chamber, such as CCP etching chamber, an ICP etching, chamber, etc. An optional temperature monitor 586 may be included to monitor and/or aid in controlling the temperature of the substrate 510 and the environment in the etching chamber 571. An optional heater 587 may be included to elevated the temperate of the substrate 510 above the equilibrium temperature at the substrate 510 during the etching process. An optional motor 588 may also be included to improve etching uniformity.

A controller 580 is operationally coupled to the valves (the first species valve 573, the second species valve 575, the optional additional gas valve 577, the optional carrier gas valve 579), and may be operationally coupled to any of the optional temperature monitor 586, the optional heater 587, the optional motor 588, and the exhaust valve 589. The controller 580 includes a processor 582 and a memory 584 (i.e., a non-transitory computer-readable medium) that stores a program including instructions that, when executed by the processor 582, perform an etching process. For example, the memory 584 may have volatile memory (e.g., random access memory (RAM)) and non-volatile memory (e.g., flash memory). Alternatively, the program may be stored in physical memory at a remote location, such as in cloud storage. The processor 582 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 6 illustrates an example method of etching larger CD features and smaller CD features into a dielectric material through a single mask using an etch stop in accordance with embodiments of the invention. The method of FIG. 6 may be combined with other methods and performed using the systems and apparatuses as described herein. For example, the method of FIG. 6 may be combined with any of the embodiments of FIGS. 1-5 and 7. Although shown in a logical order, the arrangement and numbering of the steps of FIG. 6 are not intended to be limited. The method steps of FIG. 6 may be performed in any suitable order or concurrently with one another as may be apparent to a person of skill in the art.

Referring to FIG. 6, a method 600 of etching larger CD features and smaller CD features into a dielectric material through a single mask using an etch stop includes performing both an inverse ARDE step 601 and an ARDE step 605. The inverse ARDE step 601 includes etch stop formation process 602 of forming the etch stop on bottom surfaces of the larger CD features within the dielectric material using a first gas mixture, and an inverse ARDE etching process 603 of etching the dielectric material within the smaller CD features using the first gas mixture while the etch stop prevents etching of the larger CD features.

The ARDE step 605 includes concurrently performing an ARDE etching process 606 of etching the dielectric material within the larger CD features at a first etch rate using a second gas mixture and a smaller CD ARDE etching process 616 of etching the dielectric material within the smaller CD features at a second etch rate slower than the first etch rate using the second gas mixture.

FIG. 7 illustrates an example method of RIE etching larger CD features and smaller CD features into a dielectric material through a single mask using an etch stop in accordance with embodiments of the invention. The method of FIG. 7 may be combined with other methods and performed using the systems and apparatuses as described herein. For example, the method of FIG. 7 may be combined with any of the embodiments of FIGS. 1-6. Although shown in a logical order, the arrangement and numbering of the steps of FIG. 7 are not intended to be limited. The method steps of FIG. 7 may be performed in any suitable order or concurrently with one another as may be apparent to a person of skill in the art.

Referring to FIG. 7, a method 700 of RIE etching larger CD features and smaller CD features into a dielectric material through a single mask using an etch stop includes performing both an inverse RIE-lag step 701 and an RIE-lag step 705. The inverse RIE-lag step 701 includes performing an etch stop formation process 702 of forming the etch stop on nitride bottom surfaces of the larger CD features within the dielectric material using a first gas mixture comprising CF species and CHF species in a first ratio of CF to CHF and performing an inverse RIE-lag etching process 703 of etching the dielectric material within the smaller CD features using the first gas mixture while the etch stop prevents etching of the larger CD features.

The RIE-lag step 705 includes concurrently performing an RIE-lag etching process 706 of etching the dielectric material within the larger CD features at a first etch rate using a second gas mixture comprising CF species and CHF species in a second ratio of CF to CHF that is lower than the first ratio and performing a smaller CD RIE-lag etching process 716 of etching the dielectric material within the smaller CD features at a second etch rate slower than the first etch rate using the second gas mixture.

Example embodiments of the invention are summarized here. Other embodiments can also be understood from the entirety of the specification as well as the claims filed herein.

Example 1. A method of etching larger CD features and smaller CD features into a dielectric material through a single mask using an etch stop, the method including: performing an inverse ARDE step including forming the etch stop on bottom surfaces of the larger CD features within the dielectric material using a first gas mixture, and etching the dielectric material within the smaller CD features using the first gas mixture while the etch stop prevents etching of the larger CD features; and performing an ARDE step including concurrently etching the dielectric material within the larger CD features at a first etch rate using a second gas mixture, and etching the dielectric material within the smaller CD features at a second etch rate slower than the first etch rate using the second gas mixture.

Example 2. The method of example 1, where the dielectric material includes nitride, and where the bottom surfaces on which the etch stop is formed during the inverse ARDE step are nitride bottom surfaces of the larger CD features.

Example 3. The method of example 2, where the dielectric material is an ONO stack including a plurality of oxide layers separated by nitride layers.

Example 4. The method of example 3, where the first gas mixture includes fluorocarbon (CF) species and hydrofluorocarbon (CHF) species in a first ratio of CF to CHF that is greater than about 0.45, and where the second gas mixture includes CF species and CHF species in a second ratio of CF to CHF that is less than about 0.25.

Example 5. The method of one of examples 1 to 4, further including: clogging openings of the mask corresponding to the smaller CD features to form an additional etch stop after the inverse ARDE step and before the ARDE step so that the second etch rate during the ARDE step is substantially zero, where etching the dielectric material during the inverse ARDE step includes etching the dielectric material within the smaller CD features until reaching an underlying layer.

Example 6. The method of one of examples 1 to 5, further including: performing an additional inverse ARDE step, the intermediate ARDE step including forming an intermediate etch stop on bottom surfaces of intermediate CD features and on bottom surfaces of the larger CD features using a third gas mixture, and etching the dielectric material within the smaller CD features using the third gas mixture while the intermediate etch stop prevents etching of the intermediate CD features and the larger CD features, where the inverse ARDE step further includes etching the dielectric material within the intermediate CD features using the first gas mixture while the etch stop prevents etching of the large CD features.

Example 7. A method of reactive-ion etching (RIE) larger CD features and smaller CD features into a dielectric material through a single mask using an etch stop, the method including: performing an inverse RIE-lag step including forming the etch stop on nitride bottom surfaces of the larger CD features within the dielectric material using a first gas mixture including fluorocarbon (CF) species and hydrofluorocarbon (CHF) species in a first ratio of CF to CHF, and etching the dielectric material within the smaller CD features using the first gas mixture while the etch stop prevents etching of the larger CD features; and performing an RIE-lag step including concurrently etching the dielectric material within the larger CD features at a first etch rate using a second gas mixture including CF species and CHF species in a second ratio of CF to CHF that is lower than the first ratio, and etching the dielectric material within the smaller CD features at a second etch rate slower than the first etch rate using the second gas mixture.

Example 8. The method of example 7, where the first ratio is greater than about 0.45 and the second ratio is less than about 0.25.

Example 9. The method of example 8, where the first gas mixture includes trifluoromethane (CHF₃) and at least one higher order CF species, the first ratio being about 0.48, and where the second gas mixture includes CHF₃ and at least one higher order CF species, the second ratio being about 0.23.

Example 10. The method of one of examples 7 to 9, where the inverse RIE-lag step further includes etching the dielectric material within the smaller CD features using a third gas mixture including CF species and CHF species in a third ratio of CF to CHF that is lower than the first ratio and higher than the second ratio after etching the dielectric material using the first gas mixture.

Example 11. The method of one of examples 7 to 10, further including: performing a flash step using a flash gas mixture including oxygen to remove the etch stop before the RIE-lag step.

Example 12. The method of one of examples 7 to 11, where the dielectric material is an ONO stack including a plurality of oxide layers separated by nitride layers.

Example 13. The method of one of examples 7 to 12, further including: clogging openings of the mask corresponding to the smaller CD features to form an additional etch stop after the inverse RIE-lag step and before the RIE-lag step so that the second etch rate during the RIE-lag step is substantially zero, where etching the dielectric material during the inverse RIE-lag step includes etching the dielectric material within the smaller CD features until reaching an underlying layer.

Example 14. The method of one of examples 7 to 13, further including: performing an additional inverse RIE-lag step, the intermediate RIE-lag step including forming an intermediate etch stop on nitride bottom surfaces of intermediate CD features and on nitride bottom surfaces of the larger CD features using a third gas mixture including CF species and CHF species in a third ratio of CF to CHF that is higher than the first ratio, and etching the dielectric material within the smaller CD features using the third gas mixture while the intermediate etch stop prevents etching of the intermediate CD features and the larger CD features, where the inverse RIE-lag step further includes etching the dielectric material within the intermediate CD features using the first gas mixture while the etch stop prevents etching of the large CD features.

Example 15. The method of one of examples 7 to 14, where the CD of the larger CD features is greater than four times the CD of the smaller CD features.

Example 16. An etching system including: an etching chamber; a substrate support disposed in the etching chamber and configured to support a substrate including a dielectric material; a plurality of gas sources fluidically coupled to the etching chamber through a plurality of valves; and a controller operationally coupled to the plurality of valves, the controller including a processor and a non-transitory computer-readable medium storing a program including instructions that, when executed by the processor, perform a method of etching larger CD features and smaller CD features into a dielectric material through a single mask using an etch stop, the method including: performing an inverse ARDE step including forming the etch stop on nitride bottom surfaces of the larger CD features within the dielectric material using a first gas mixture, and etching the dielectric material within the smaller CD features using the first gas mixture while the etch stop prevents etching of the larger CD features; and performing an ARDE step including concurrently etching the dielectric material within the larger CD features at a first etch rate using a second gas mixture, and etching the dielectric material within the smaller CD features at a second etch rate slower than the first etch rate using the second gas mixture.

Example 17. The etching system of example 16, where the plurality of gas sources includes a fluorocarbon (CF) gas source and a hydrofluorocarbon (CHF) gas source, where the first gas mixture includes CF species and CHF species in a first ratio of CF to CHF, and where the second gas mixture includes CF species and CHF species in a second ratio of CF to CHF that is lower than the first ratio.

Example 18. The etching system of example 17, where the method further includes: performing an additional inverse ARDE step, the intermediate ARDE step including forming an intermediate etch stop on nitride bottom surfaces of intermediate CD features and on nitride bottom surfaces of the larger CD features using a third gas mixture including CF species and CHF species in a third ratio of CF to CHF that is higher than the first ratio, and etching the dielectric material within the smaller CD features using the third gas mixture while the intermediate etch stop prevents etching of the intermediate CD features and the larger CD features, where the inverse ARDE step further includes etching the dielectric material within the intermediate CD features using the first gas mixture while the etch stop prevents etching of the large CD features.

Example 19. The etching system of one of examples 17 and 18, where the method further includes: clogging openings of the mask corresponding to the smaller CD features after the inverse RIE-lag step and before the RIE-lag step so that the second etch rate during the RIE-lag step is substantially zero, where etching the dielectric material during the inverse RIE-lag step includes etching the dielectric material within the smaller CD features until reaching an underlying layer.

Example 20. The etching system of one of examples 17 to 19, where the plurality of gas sources includes and oxygen gas source, and where the method further includes: performing a flash step using a flash gas mixture including oxygen to remove the etch stop before the ARDE step.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of etching larger critical dimension (CD) features and smaller CD features into a dielectric material through a single mask using an etch stop, the method comprising:
performing an inverse aspect ratio-dependent etch (ARDE) step comprising
forming the etch stop on bottom surfaces of the larger CD features within the dielectric material using a first gas mixture, and
etching the dielectric material within the smaller CD features using the first gas mixture while the etch stop prevents etching of the larger CD features; and
performing an ARDE step comprising concurrently
etching the dielectric material within the larger CD features at a first etch rate using a second gas mixture, and
etching the dielectric material within the smaller CD features at a second etch rate slower than the first etch rate using the second gas mixture.

2. The method of claim 1, wherein the dielectric material comprises nitride, and wherein the bottom surfaces on which the etch stop is formed during the inverse ARDE step are nitride bottom surfaces of the larger CD features.

3. The method of claim 2, wherein the dielectric material is an ONO stack comprising a plurality of oxide layers separated by nitride layers.

4. The method of claim 3,
wherein the first gas mixture comprises fluorocarbon (CF) species and hydrofluorocarbon (CHF) species in a first ratio of CF to CHF that is greater than about 0.45, and
wherein the second gas mixture comprises CF species and CHF species in a second ratio of CF to CHF that is less than about 0.25.

5. The method of claim 1, further comprising:
clogging openings of the mask corresponding to the smaller CD features to form an additional etch stop after the inverse ARDE step and before the ARDE step so that the second etch rate during the ARDE step is substantially zero,
wherein etching the dielectric material during the inverse ARDE step comprises etching the dielectric material within the smaller CD features until reaching an underlying layer.

6. The method of claim 1, further comprising:
performing an additional inverse ARDE step, the intermediate ARDE step comprising
forming an intermediate etch stop on bottom surfaces of intermediate CD features and on bottom surfaces of the larger CD features using a third gas mixture, and
etching the dielectric material within the smaller CD features using the third gas mixture while the intermediate etch stop prevents etching of the intermediate CD features and the larger CD features,
wherein the inverse ARDE step further comprises etching the dielectric material within the intermediate CD features using the first gas mixture while the etch stop prevents etching of the large CD features.

7. A method of reactive-ion etching (RIE) larger critical dimension (CD) features and smaller CD features into a dielectric material through a single mask using an etch stop, the method comprising:
performing an inverse RIE-lag step comprising
forming the etch stop on nitride bottom surfaces of the larger CD features within the dielectric material using a first gas mixture comprising fluorocarbon (CF) species and hydrofluorocarbon (CHF) species in a first ratio of CF to CHF, and
etching the dielectric material within the smaller CD features using the first gas mixture while the etch stop prevents etching of the larger CD features; and
performing an RIE-lag step comprising concurrently
etching the dielectric material within the larger CD features at a first etch rate using a second gas mixture comprising CF species and CHF species in a second ratio of CF to CHF that is lower than the first ratio, and
etching the dielectric material within the smaller CD features at a second etch rate slower than the first etch rate using the second gas mixture.

8. The method of claim 7, wherein the first ratio is greater than about 0.45 and the second ratio is less than about 0.25.

9. The method of claim 8,
wherein the first gas mixture comprises trifluoromethane (CHF₃) and at least one higher order CF species, the first ratio being about 0.48, and
wherein the second gas mixture comprises CHF₃ and at least one higher order CF species, the second ratio being about 0.23.

10. The method of claim 7, wherein the inverse RIE-lag step further comprises etching the dielectric material within the smaller CD features using a third gas mixture comprising CF species and CHF species in a third ratio of CF to CHF that is lower than the first ratio and higher than the second ratio after etching the dielectric material using the first gas mixture.

11. The method of claim 7, further comprising:
performing a flash step using a flash gas mixture comprising oxygen to remove the etch stop before the RIE-lag step.

12. The method of claim 7, wherein the dielectric material is an ONO stack comprising a plurality of oxide layers separated by nitride layers.

13. The method of claim 7, further comprising:
clogging openings of the mask corresponding to the smaller CD features to form an additional etch stop after the inverse RIE-lag step and before the RIE-lag step so that the second etch rate during the RIE-lag step is substantially zero,
wherein etching the dielectric material during the inverse RIE-lag step comprises etching the dielectric material within the smaller CD features until reaching an underlying layer.

14. The method of claim 7, further comprising:
performing an additional inverse RIE-lag step, the intermediate RIE-lag step comprising
forming an intermediate etch stop on nitride bottom surfaces of intermediate CD features and on nitride bottom surfaces of the larger CD features using a third gas mixture comprising CF species and CHF species in a third ratio of CF to CHF that is higher than the first ratio, and
etching the dielectric material within the smaller CD features using the third gas mixture while the intermediate etch stop prevents etching of the intermediate CD features and the larger CD features,
wherein the inverse RIE-lag step further comprises etching the dielectric material within the intermediate CD features using the first gas mixture while the etch stop prevents etching of the large CD features.

15. The method of claim 7, wherein the CD of the larger CD features is greater than four times the CD of the smaller CD features.

16. An etching system comprising:
an etching chamber;
a substrate support disposed in the etching chamber and configured to support a substrate comprising a dielectric material;
a plurality of gas sources fluidically coupled to the etching chamber through a plurality of valves; and
a controller operationally coupled to the plurality of valves, the controller comprising a processor and a non-transitory computer-readable medium storing a program including instructions that, when executed by the processor, perform a method of etching larger critical dimension (CD) features and smaller CD features into a dielectric material through a single mask using an etch stop, the method comprising:
performing an inverse aspect ratio-dependent etch (ARDE) step comprising
forming the etch stop on nitride bottom surfaces of the larger CD features within the dielectric material using a first gas mixture, and
etching the dielectric material within the smaller CD features using the first gas mixture while the etch stop prevents etching of the larger CD features; and
performing an ARDE step comprising concurrently
etching the dielectric material within the larger CD features at a first etch rate using a second gas mixture, and
etching the dielectric material within the smaller CD features at a second etch rate slower than the first etch rate using the second gas mixture.

17. The etching system of claim 16,
wherein the plurality of gas sources comprises a fluorocarbon (CF) gas source and a hydrofluorocarbon (CHF) gas source,
wherein the first gas mixture comprises CF species and CHF species in a first ratio of CF to CHF, and
wherein the second gas mixture comprises CF species and CHF species in a second ratio of CF to CHF that is lower than the first ratio.

18. The etching system of claim 17, wherein the method further comprises:
performing an additional inverse ARDE step, the intermediate ARDE step comprising
forming an intermediate etch stop on nitride bottom surfaces of intermediate CD features and on nitride bottom surfaces of the larger CD features using a third gas mixture comprising CF species and CHF species in a third ratio of CF to CHF that is higher than the first ratio, and
etching the dielectric material within the smaller CD features using the third gas mixture while the intermediate etch stop prevents etching of the intermediate CD features and the larger CD features,
wherein the inverse ARDE step further comprises etching the dielectric material within the intermediate CD features using the first gas mixture while the etch stop prevents etching of the large CD features.

19. The etching system of claim 17, wherein the method further comprises:
clogging openings of the mask corresponding to the smaller CD features after the inverse RIE-lag step and before the RIE-lag step so that the second etch rate during the RIE-lag step is substantially zero,
wherein etching the dielectric material during the inverse RIE-lag step comprises etching the dielectric material within the smaller CD features until reaching an underlying layer.

20. The etching system of claim 17, wherein the plurality of gas sources comprises and oxygen gas source, and wherein the method further comprises:
performing a flash step using a flash gas mixture comprising oxygen to remove the etch stop before the ARDE step.
